(19) United States
(12) Patent Application Publication
(10) Pub. No.: US 2002/0132063 A1
(43) Pub. Date: Sep. 19, 2002

(54) Multilayered film forming method, apparatus for controlling vacuum film forming apparatus, and vacuum film forming apparatus

(76) Inventors: Nao Watanabe, Hyogo (JP); Takahiko Kondo, Hyogo (JP); Kenji Yamakawa, Hyogo (JP)

Correspondence Address: MARSHALL, GERSTEIN & BORUN, 6300 SEARS TOWER, 233 SOUTH WACKER, CHICAGO, IL, 60606-6357, US

(21) Appl. No.: 10/087,157

(22) Filed: Mar. 1, 2002

(30) Foreign Application Priority Data
Mar. 2, 2001 (JP) 2001-57830

(51) Int. Cl. C23C 16/00; B05D 1/36

(52) U.S. Cl. 427/596; 118/723 VE; 118/723 EB; 427/255.7; 427/402

(57) ABSTRACT

A multilayered film forming method for forming a plurality of sequentially deposited film layers on a substrate by using a plurality of electron guns to evaporate a plurality of film materials in a substantially vacuum chamber, wherein film layer forming processes for forming said plurality of film layers include main heating processes for evaporating the film materials corresponding to the respective film layers by said electron guns, respectively and preliminary heating processes for preliminarily heating the film materials corresponding to the respective film layers by said electron guns, respectively in advance of the respective main heating processes, and with respect to at least two successive ones of the film layer forming processes, before the main heating process of a precedently executed film layer forming process is terminated, the preliminary heating process of the subsequently executed film layer forming process is commenced.

### BACKGROUND OF THE INVENTION

1. Field of the Invention

This invention relates to a multilayered film forming method, an apparatus for controlling a vacuum film forming apparatus, and a vacuum film forming apparatus.

2. Description of the Related Art

Generally, a vacuum film forming apparatus has, within its vacuum chamber, a substrate on which a film is to be formed and an evaporating source, opposed to the substrate, for evaporating a film material. The film material evaporated by the evaporating source is finally deposited onto the substrate, thereby forming the film.

Among the other kinds of evaporating sources for evaporating film materials, there exists one that has an electron gun for irradiating an electron beam to a film material to heat the film material, thereby evaporating the film material toward the substrate.

When this heating of film material using the electron gun is performed, a preliminary heating process for preliminarily heating the film material may be executed prior to a main heating process for evaporating the film material toward the substrate. That is, preliminarily heating the film material prior to the main heating process allows the film material to be more swiftly and smoothly evaporated during the following main heating process.

If a film formation is performed via processes using one or more electron guns to evaporate film materials, a multilayered film comprising two or more film layers may be formed. Such multilayered films may be used as optical films exhibiting various optical characteristics, or may be used as optical filters for optical communications. Particularly in recent years, the demand for such multilayered films has been rapidly increasing in application for IT (information technology) fields.

When a multilayered film is applied for any particular use, the number of the layers constituting the multilayered film may be an important condition. For example, in a case when a multilayered film is used as an optical filter of a wavelength division multiplexing system for optical communications, the wavelength band of the lights that can pass through the filter may be determined by the number of the layers constituting the multilayered film.

When a multilayered film is formed via processes using one or more electron guns to heat film materials, the preliminary and main heating processes may be repeated for forming the layers constituting the multilayered film in such a manner that after a set of preliminary and main heating processes for forming one film layer is completed, another set of preliminary and main heating processes is executed with respect to another film layer to be formed next.

However, if a multilayered film is formed by executing, after the completion of a set of preliminary and main heating processes for forming one film layer, another set of preliminary and main heating processes for forming another film layer, then the time required to complete the whole film formation is determined by a sum of the times required to complete the respective sets of preliminary and main heating processes. Accordingly, the time required to complete the formation of a multilayered film significantly increases with an increasing number of the layers constituting the multilayered film, resulting in an increased cycle time.

### SUMMARY OF THE INVENTION

It is an object of the present invention to provide a multilayered film forming method, an apparatus for controlling a vacuum film forming apparatus, and a vacuum film forming apparatus, which can prevent the time required to complete the formation of a multilayered film from increasing, while executing the preliminary and main heating processes using one or more electron guns to heat film materials.

In order to accomplish the above object, the multilayered film forming method of the present invention is one for forming a plurality of sequentially deposited film layers on a substrate by using a plurality of electron guns to evaporate a plurality of film materials in a substantially vacuum chamber. In this multilayered film forming method, film layer forming processes for forming said plurality of film layers include main heating processes for evaporating the film materials corresponding to the respective film layers by said electron guns, respectively and preliminary heating processes for preliminarily heating the film materials corresponding to the respective film layers by said electron guns, respectively in advance of the respective main heating processes, and with respect to at least two successive ones of the film layer forming processes, before the main heating process of a precedently executed film layer forming process is terminated, the preliminary heating process of the subsequently executed film layer forming process is commenced.

According to the above structure, in a case of forming a multilayered film, before the main heating process for forming one film layer is completed, the preliminary heating process for heating the film material of another film layer to be formed next is commenced. Therefore, when a multilayered film is formed by repeatedly executing the preliminary and main heating processes a predetermined number of times equal to the number of film layers to be formed, the total time required to form all the film layers can be shortened.

The number of the foregoing plurality of film layers to be formed may be 100 or more. According to the film forming method of the present invention, even in a case when a multilayered film to be formed comprise 100 or more film layers, it can be formed in a short time.

The foregoing plurality of film layers may constitute an optical filter for optical communications. As known in the arts, optical filters for optical communications are composed of multilayered films. When a multilayered film to be used as an optical filter is formed according to the present invention, it can be formed in a short time.

A control apparatus of the present invention is one for controlling a vacuum film forming apparatus that forms a plurality of sequentially deposited film layers on a substrate by using a plurality of electron guns to evaporate a plurality of film materials in a substantially vacuum chamber. This control apparatus controls the vacuum film forming apparatus in such a manner that film layer forming processes for forming said plurality of film layers include main heating processes for evaporating the film materials corresponding to the respective film layers by said electron guns, respectively and preliminary heating processes for preliminarily heating the film materials corresponding to the respective film layers by said electron guns, respectively in advance of the respective main heating processes, and with respect to at least two successive ones of the film layer forming processes, before the main heating process of a precedently executed film layer forming process is terminated, the preliminary heating process of the subsequently executed film layer forming process is commenced.

Because of the above structure, the control apparatus of the present invention for controlling a vacuum film forming apparatus can shorten, in a case of forming a multilayered film, the time required to form all the layers constituting the multilayered film.

A vacuum film forming apparatus of the present invention forms a plurality of sequentially deposited film layers on a substrate by using a plurality of electron guns to evaporate a plurality of film materials in a substantially vacuum chamber. In this vacuum film forming apparatus, film layer forming processes for forming said plurality of film layers include main heating processes for evaporating the film materials corresponding to the respective film layers by said electron guns, respectively and preliminary heating processes for preliminarily heating the film materials corresponding to the respective film layers by said electron guns, respectively in advance of the respective main heating processes, and with respect to at least two successive ones of the film layer forming processes, before the main heating process of a precedently executed film layer forming process is terminated, the preliminary heating process of the subsequently executed film layer forming process is commenced.

Because of the above structure, the vacuum film forming apparatus of the present invention can shorten, in a case of forming a multilayered film, the time required to form all the layers constituting the multilayered film.

These objects as well as other objects, features and advantages of the present invention will become more apparent to those skilled in the art from the following description with reference to the accompanying drawings.

### BRIEF DESCRIPTION OF THE DRAWINGS

FIG. 1 is a schematic diagram of a vacuum film forming apparatus that can implement the present invention.

FIG. 2 is a side cross-sectional view of the vacuum film forming apparatus, taken along the line II-II of FIG. 1, and its viewing direction is indicated by the arrows 11 of FIG. 1.

FIG. 3 is a cross-sectional view of the vacuum film forming apparatus, taken along the line III-III of FIG. 1, and its viewing direction is indicated by the arrows III of FIG. 1.

FIG. 4 is a diagram showing conditions for executing the preliminary and main heating processes of the present invention.

### DETAILED DESCRIPTION OF THE PREFERRED EMBODIMENTS

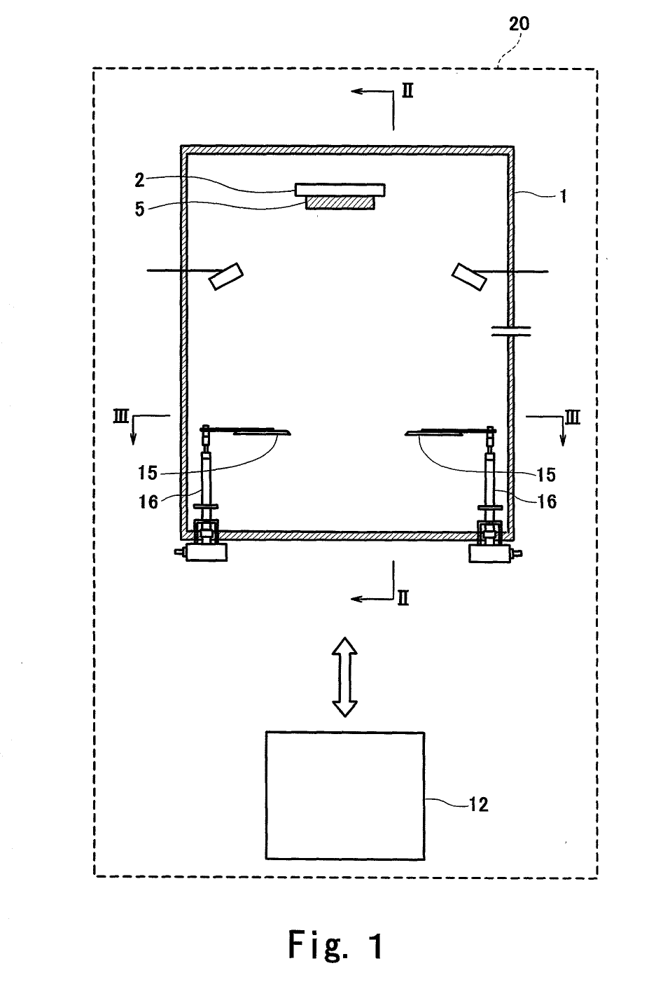

Embodiments of the present invention will be described below with reference to FIGS. 1 through 4.

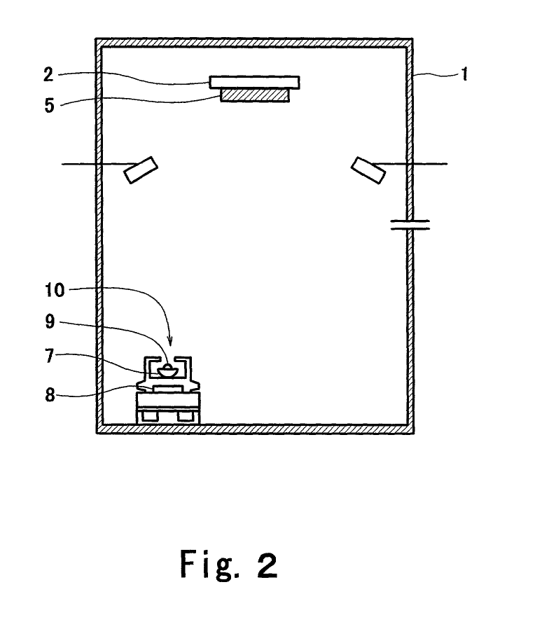

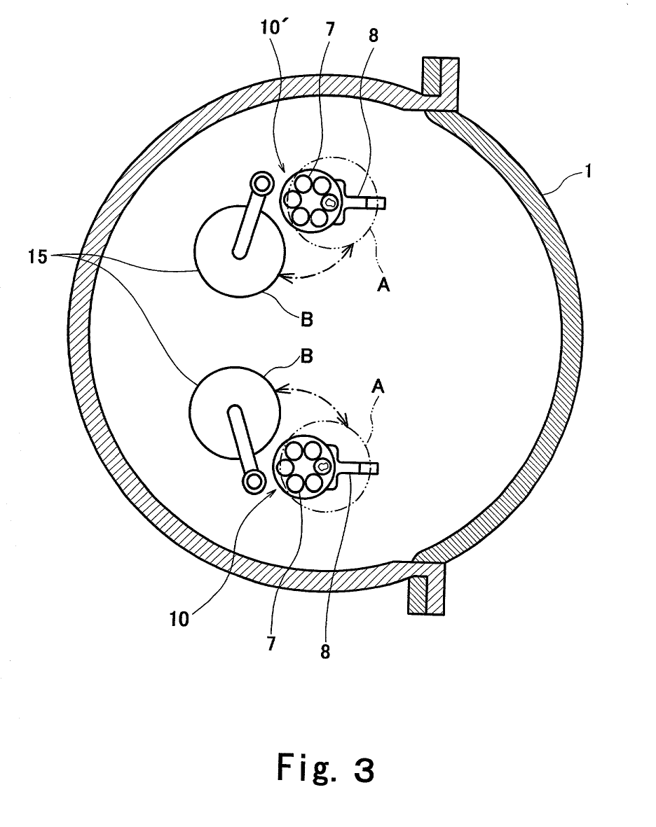

FIG. 1 is a front elevation of a vacuum film forming apparatus 20 that can implement the multilayered film forming method of the present invention, and schematically shows a typical structure of the vacuum film forming apparatus 20. FIG. 2 is a side, cross-sectional view taken along the line II-II of FIG. 1, and its viewing direction is indicated by the arrows II. FIG. 3 is a cross-sectional view taken along the line III-III of FIG. 1, and its viewing direction is indicated by the arrows III.

The film forming apparatus 20 comprises a vacuum vapor deposition apparatus and is so constructed that a film can be formed on a substrate 5 by a so-called vacuum vapor deposition. The internal space of a vacuum chamber 1 can be evacuated, by use of an evacuation pomp, to exhibit a desired vacuum atmosphere. A substrate holder 2 for holding the substrate 5 on which the film is to be formed is disposed at an upper position within the vacuum chamber 1.

Evaporating sources 10 and 10′ for evaporating film materials in the internal space of the chamber 1 are disposed at lower positions within the chamber 1. The evaporating sources 10 and 10′ are so constructed that they each include crucibles 7 and an electron gun 8 as shown in FIGS. 2 and 3.

The electron gun 8 is adapted to irradiate an electron beam toward a respective crucible 7 into which a film material 9 is supplied. The film material 9 in the respective crucible 7 is heated by the irradiation of the electron beam by the electron gun 8.

The evaporating sources 10 and 10′ have a plurality of crucibles 7 as shown in FIG. 3, respectively. These crucibles 7 are adapted to be sequentially positioned to an electron beam irradiation position in the order of forming the corresponding film layers on the substrate 5. This sequential positioning of the crucibles 7 is controlled by a control apparatus 12 that will be described later.

The intensity of the electron beam that determines the strength of heating the film material 9 is so arranged as to be determined by the intensity of the beam current supplied to the electron gun 8. The electron gun 8 is adapted to be supplied with a predetermined intensity of beam current required to execute a preliminary heating process that will be described later and with a predetermined intensity of beam current required to execute a main heating process that will be also described later. The commencement and stop of the electron beam irradiation performed by the electron gun 8 as well as the intensity of the beam current supplied to the electron gun 8 are so arranged as to be controlled by the control apparatus 12 that will be described later.

Masking shields 15 that inhibit evaporated film material 9 from depositing onto the substrate 5 are disposed at lower positions within the chamber 1 and are so adapted that they can cover the spaces just above the respective evaporating sources 10 and 10′. These shields 15 each are so driven as to revolve around a respective supporting column 16 as shown in FIG. 3. The force of thus driving the shields 15 is so arranged as to be provided by a driving mechanism such as a motor (not shown).

The driving of the shields 15 is performed such that they each move between a closing position A where they cover the space just above the crucibles 7 and an opening position B where they do not exist just above the crucibles 7. When the shields 15 are situated at the respective closing positions A, they close the spaces just above the crucibles 7 so that the film material 9, even if evaporated by heating, will not deposit onto the substrate 5. Contrarily, when the shields 15 are situated at the respective opening positions B, the spaces just above the crucibles 7 are open so that the film material 9, if evaporated by heating, can deposit onto the substrate 5.

The shields 15 are situated at the closing and opening positions A and B during the preliminary and main heating processes, respectively, that will be described later. Driving the shields 15 such that they are situated at the closing or opening positions A or B is controlled by the control apparatus 12 that will be described later.

When the electron guns 8 each irradiate an electron beam to the film material 9, the evaporating sources 10 and 10′ described above can be controlled independently of each other. Also, the shields 15 can be controlled independently of each other in position relative to the evaporating sources 10 and 10′. In this way, the preliminary and main heating processes can be executed independently of each other by the evaporating sources 10 and 10′.

The control apparatus 12 controls the film forming processes executed by the film forming apparatus 20 by outputting control signals for controlling the operations of the devices within the film forming apparatus 20 other than the control apparatus 12 and by receiving input signals outputted by those devices. The signal inputting/outputting between the control apparatus 12 and the other devices is so arranged to be performed via an interface mechanism, A/D conversion mechanism and so on (all not shown) known in the art of digital controlling.

The control apparatus 12 includes a programmable controller and is adapted to allow any desired film forming procedure to be written in a program that is provided to the programmable controller. Thus, the control apparatus 12 can specify, in advance, any desired film forming conditions to be executed by the film forming apparatus 20, thereby allowing any desired film forming processes to be executed. The programmable controller may comprise, for example, a sequencer, which allows the contents of any desired processes to be easily written in the program, and hence allows any desired film forming processes to be easily specified.

The contents of the program to be provided to the programmable controller of the control apparatus 12 include conditions for operating the evaporating sources 10 and 10′ and those for operating the shields 15 in position relative to the respective evaporating sources 10 and 10′.

The conditions for operating the evaporating sources 10 and 10′ include conditions concerning the beam currents to be supplied to the respective electron guns 8; specifically, for example, the intensities of the beam currents, the timings of commencing and stopping the supply of the beam currents, and the variation of the beam currents with time. The conditions for operating the shields 15 include those concerning at which the shields 15 should be situated, the closing positions A or the opening positions B.

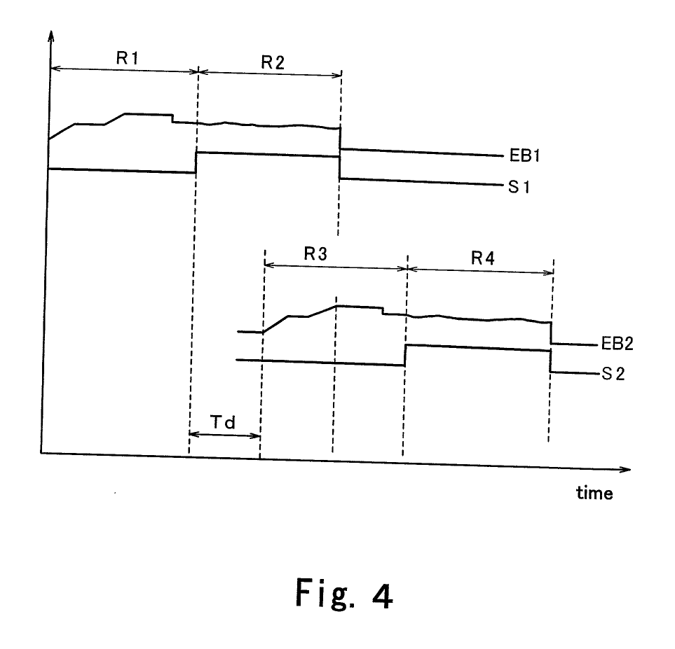

Next, the conditions for operating the evaporating sources 10 and 10′ and those for operating the shields 15 will now be described with reference to FIG. 4. In this figure, the axis of abscissas corresponds to time, while the axis of ordinates corresponds to the intensities of the beam currents to be supplied to the respective electron guns 8 and also corresponds to ON/OFF signals for driving the shields 15 to the closing positions A or the opening positions B.

In FIG. 4, “EB1” represents the beam current to be supplied to the electron gun 8 of the evaporating source 10, while “EB2” represents the beam current to be supplied to the electron gun 8 of the evaporating source 10′. In FIG. 4, “S1” represents the ON/OFF signals for driving the shield 15 associated with the evaporating source 10, while “S2” represents the ON/OFF signals for driving the shield 15 associated with the evaporating source 10′.

Also in FIG. 4, the range defined by a region R1 concerning the condition for operating the evaporating source 10 corresponds to the condition for executing the preliminary heating process in which the film material 9 is heated but not vapor deposited onto the substrate 5, while the range defined by a region R2 also concerning the condition of the evaporating source 10 corresponds to the condition for executing the main heating process in which the film material 9 is heated and vapor deposited onto the substrate 5.

Also in FIG. 4, the range defined by a region R3 concerning the condition for operating the evaporating source 10′ corresponds to the condition for executing the preliminary heating process in which the film material 9 is heated but not vapor deposited onto the substrate 5, while the range defined by a region R4 also concerning the condition of the evaporating source 10′ corresponds to the condition for executing the main heating process in which the film material 9 is heated and vapor deposited onto the substrate 5.

The EB1 and EB2 of FIG. 4 in the ranges defined by the regions R1 and R3, respectively, represent the currents whose intensities are required for the respective preliminary heatings of the film materials 9. Also, the EB1 and EB2 of FIG. 4 in the ranges defined by the regions R2 and R4, respectively, represent the currents whose intensities are required to evaporate and deposit the respective film materials 9 onto the substrate 5.

The S1 and S2 of FIG. 4 in the ranges defined by the regions R1 and R3, respectively, represent the OFF signals for positioning the shields 15 at the respective closing positions A. The S1 and S2 of FIG. 4 in the ranges defined by the regions R2 and R4, respectively, represent the ON signals for positioning the shields 15 at the respective opening positions B.

If the evaporating sources 10 and 10′ are operated in accordance with the conditions specified in FIG. 4, the preliminary heating process executed by the evaporating source 10′ commences in a time period Td following the commencement of and prior to the termination of the main heating process executed by the evaporating source 10. That is, while the evaporating source 10 is executing its main heating process to form a film layer on the substrate 5, the evaporating source 10′ starts to execute its preliminary heating process to heat the material of another film layer to be formed next on the substrate 5. In this way, the total time required to complete the formation of a multilayered film comprising two or more layers can be shorted, as compared with a case when a multilayered film comprising two or more layers is formed by starting, after the termination of a main heating process to form one film layer, a preliminary heating process to form the next film layer.

If the conditions specified in FIG. 4 are used to form a respective film layer whose thickness is on the order of about 300 nm, then the times required to complete the respective preliminary heating processes corresponding to the ranges defined by the regions R1 and R3 are on the order of about 10 minutes, and the times required to complete the respective main heating processes corresponding to the ranges defined by the regions R2 and R4 are on the order of about an hour.

If the times required to complete the respective preliminary heating processes are on the order of about 10 minutes and if the times required to complete the respective main heating processes are on the order of about an hour as stated above, then the time period Td in which the preliminary heating process for forming the next film layer is commenced may be established within a range whose maximum is about 30 minutes.

If the film forming apparatus 20 described above is used to perform a film formation, any desired multilayered films suitable for any particular uses can be obtained by appropriately selecting film materials and film layer thickness when those films are formed. For example, a multilayered film thus formed may be used as an optical filter for optical communications.

The optical filter for optical communications is used in an optical multiplexer or optical demultiplexer in a wavelength division multiplexing (WDM) system. The optical multiplexer is a device for transmitting to an optical fiber a multiple of light lays of different wavelengths, while the optical demultiplexer is a device for splitting a light beam transmitted through an optical fiber into light lays having their respective different wavelengths for further transmission. The range of the optical wavelengths (wavelength band) that can be covered by the optical filer, that is, the number of channels in the optical communications is determined by the number of the layers of a multilayered film constituting the optical filter. In general, the optical filter for optical communications is so formed as to have about 100 to 200 film layers.

If the film forming apparatus 20 is used to implement the present invention to form a multilayered film as optical filter, then the time required to complete the formation of the whole multilayered film can be shortened because of executing, while executing a main heating process for one film layer, a preliminary heating process for heating the material of another film layer to be formed next as described above.

The present invention was described above as an example wherein each evaporating source is equipped with one electron gun for heating the film material in a respective one of the crucibles. The present invention, however, is not limited to this example. What is essential is that there exist a plurality of electron guns as well as a plurality of crucibles so that, while a main heating process for heating a film material held in a crucible is being executed by an electron gun, a preliminary heating process for heating a film material held in another crucible can be executed by another electron gun.

The present invention was also described above as an example wherein the film forming apparatus 20 comprises a vacuum vapor deposition apparatus. The present invention, however, is not limited to the vacuum vapor deposition but may be applied for any type of film formation only if processes of heating and evaporating, by use of electron guns, film materials held in the respective crucibles are included in the total process of forming the film on the substrate held within a vacuum chamber.

The present invention can be successfully implemented, for example, when applied for, as a type of film formation, ion plating if it is possible to execute, while executing a main heating process for heating a film material held in a crucible by use of an electron gun, a preliminary heating process for heating a film material held in another crucible by use of another electron gun.

If a film formation is performed by use of the ion plating, it can be completed via processes in which film materials evaporated by the respective main heating processes are further ionized by an electric field formed within the vacuum chamber. Also in this film formation using the ion plating, the time required to complete a formation of the whole multilayered film can be shortened because of the foregoing parallel executions of a main heating process for forming one film layer and a preliminary heating process for heating the film material of another film layer to be formed next.

As the present invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

What is claimed is:

1. A multilayered film forming method for forming a plurality of sequentially deposited film layers on a substrate by using a plurality of electron guns to evaporate a plurality of film materials in a substantially vacuum chamber,
wherein film layer forming processes for forming said plurality of film layers include main heating processes for evaporating the film materials corresponding to the respective film layers by said electron guns, respectively and preliminary heating processes for preliminarily heating the film materials corresponding to the respective film layers by said electron guns, respectively in advance of the respective main heating processes, and
with respect to at least two successive ones of the film layer forming processes, before the main heating process of a precedently executed film layer forming process is terminated, the preliminary heating process of the subsequently executed film layer forming process is commenced.

2. The multilayered film forming method according to claim 1, wherein the number of said plurality of film layers is 100 or more.

3. The multilayered film forming method according to claim 2, wherein said plurality of film layers constitute an optical filter for optical communications.

4. A control apparatus for controlling a vacuum film forming apparatus that forms a plurality of sequentially deposited film layers on a substrate by using a plurality of electron guns to evaporate a plurality of film materials in a substantially vacuum chamber,
said control apparatus controlling said vacuum film forming apparatus in such a manner that:
film layer forming processes for forming said plurality of film layers include main heating processes for evaporating the film materials corresponding to the respective film layers by said electron guns, respectively and preliminary heating processes for preliminarily heating the film materials corresponding to the respective film layers by said electron guns, respectively in advance of the respective main heating processes; and that
with respect to at least two successive ones of said film layer forming processes, before the main heating process of a precedently executed film layer forming process is terminated, the preliminary heating process of the subsequently executed film layer forming process is commenced.

5. A vacuum film forming apparatus for forming a plurality of sequentially deposited film layers on a substrate by using a plurality of electron guns to evaporate a plurality of film materials in a substantially vacuum chamber,
wherein film layer forming processes for forming said plurality of film layers include main heating processes for evaporating the film materials corresponding to the respective film layers by said electron guns, respectively and preliminary heating processes for preliminarily heating the film materials corresponding to the respective film layers by said electron guns, respectively in advance of the respective main heating processes, and
with respect to at least two successive ones of the film layer forming processes, before the main heating process of a precedently executed film layer forming process is terminated, the preliminary heating process of the subsequently executed film layer forming process is commenced.
